(19) United States
(12) Patent Application Publication
(10) Pub. No.: US 2025/0286292 A1
(43) Pub. Date: Sep. 11, 2025

(54) POWER SEMICONDUCTOR MODULE HAVING POWER LEADS AND PINS, POWER ELECTRONIC SYSTEM AND METHOD FOR FABRICATING A POWER SEMICONDUCTOR MODULE

(71) Applicant: Infineon Technologies AG, Neubiberg (DE)

(72) Inventors: Peter Weiß, Kelheim (DE); Stefan Wötzel, Erfurt (DE); Mark Nils Münzer, Neubiberg (DE)

(21) Appl. No.: 19/062,127

(22) Filed: Feb. 25, 2025

(30) Foreign Application Priority Data
Mar. 6, 2024 (DE) 102024202103.2

(51) Int. Cl. H01R 12/58; H01L 23/31; H01L 23/538; H01L 25/18

(52) U.S. Cl. CPC H01R 12/585; H01L 23/3107; H01L 23/538; H01L 25/18

(57) ABSTRACT

A power semiconductor module includes: an encapsulation body having a first side, an opposite second side, and lateral sides connecting the first and second sides; a first and a second power lead exposed from a first one of the lateral sides, the first power lead configured to provide a first DC+ connection and the second power lead configured to provide a first DC− connection; a plurality of power semiconductor dies encapsulated by the encapsulation body and connected to the first and second power leads; and a first and a second pin exposed from the encapsulation body and arranged perpendicular to the first and second power leads, the first pin configured to provide a second DC+ connection and the second pin configured to provide a second DC− connection.

### TECHNICAL FIELD

This disclosure relates in general to a power semiconductor module, in particular a power semiconductor module comprising power leads as well as pins. This disclosure further relates to a power electronic system comprising such a power semiconductor module as well as to a method for fabricating such a power semiconductor module.

### BACKGROUND

Semiconductor modules, in particular power semiconductor modules, may be configured to operate with a high voltage of e.g. 100V or more, or 500V or more, or 1.2 kV or more, or 2 kV or more and/or a strong current of e.g. 1 A or more, or 10 A or more, or 100 A or more. Furthermore, semiconductor modules, in particular power semiconductor modules, may be configured for fast switching. Modules which comprise (power) semiconductor dies based on e.g. SiC or GaN may enable such fast switching speeds. However, with fast switching parasitic inductances may be problematic for example because parasitic inductances in the commutation loop may cause strong voltage overshoots of e.g. the drain-source current of an involved transistor due to fast commutation of the involved currents. Such an overshoot may exceed the maximum breakdown voltage of the transistor device and may cause damage.

### SUMMARY

Various aspects pertain to a power electronic system, comprising: a power semiconductor module, comprising: an encapsulation body comprising a first side, an opposite second side and lateral sides connecting the first and second sides, a first and a second power lead exposed from a first one of the lateral sides, the first power lead configured to provide a first DC+ connection and the second power lead configured to provide a first DC− connection, a plurality of power semiconductor dies encapsulated by the encapsulation body and connected to the first and second power leads, a first and a second pin exposed from the encapsulation body and arranged perpendicular to the first and second power leads, the first pin configured to provide a second DC+ connection and the second pin configured to provide a second DC− connection; and a driver board arranged over the first side of the encapsulation body and comprising driver circuitry configured to drive the power semiconductor dies of the power semiconductor module, wherein the driver board further comprises a first capacitor connected to the first and second pins to provide a first commutation loop.

Various aspects pertain to a power semiconductor module, comprising: an encapsulation body comprising a first side, an opposite second side and lateral sides connecting the first and second sides; a first and a second power lead exposed from a first one of the lateral sides, the first power lead configured to provide a first DC+ connection and the second power lead configured to provide a first DC− connection; a plurality of power semiconductor dies encapsulated by the encapsulation body and connected to the first and second power leads; and a first and a second pin exposed from the encapsulation body and arranged perpendicular to the first and second power leads, the first pin configured to provide a second DC+ connection and the second pin configured to provide a second DC− connection.

Various aspects pertain to a method for fabricating a power semiconductor module, the method comprising: connecting a plurality of power semiconductor dies to a first and second power lead, the first power lead configured to provide a first DC+ connection and the second power lead configured to provide a first DC− connection; encapsulating the plurality of power semiconductor dies with an encapsulation body, the encapsulation body comprising a first side, an opposite second side and lateral sides connecting the first and second sides, such that the first and second power leads are exposed from a first one of the lateral sides; and providing a first and second pin exposed from the encapsulation body and arranged perpendicular to the first and second power leads, the first pin configured to provide a second DC+ connection and the second pin configured to provide a second DC− connection.

### BRIEF DESCRIPTION OF THE DRAWINGS

The accompanying drawings illustrate examples and together with the description serve to explain principles of the disclosure. Other examples and many of the intended advantages of the disclosure will be readily appreciated in view of the following detailed description. The elements of the drawings are not necessarily to scale relative to each other. Identical reference numerals designate corresponding similar parts.

FIGS. 1A and 1B show a top down view (FIG. 1A) and a side view (FIG. 1B) of a power semiconductor module which comprises power leads and which additionally comprises pins, both of which providing respective DC+ and DC− connections.

FIGS. 2A and 2B show a perspective view of a power electronic system (FIG. 2A) and a top down view of a power semiconductor module comprised in the power electronic system (FIG. 2B).

FIGS. 3A and 3B show a top down view (FIG. 3A) and a side view (FIG. 3B) of a further power semiconductor module.

FIG. 4 shows a sectional view of the power semiconductor module of FIGS. 1A and 1B according to a specific example.

FIG. 5 is a flow chart of an exemplary method for fabricating a power semiconductor module.

### DETAILED DESCRIPTION

In the following detailed description, known structures and elements are shown in schematic form in order to facilitate describing one or more aspects of the disclosure. In this regard, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

The semiconductor die(s) of a power semiconductor module may be covered with an electrically insulating encapsulation material in order to be embedded in an encapsulation. The encapsulation material may, for example, comprise or consist of any appropriate plastic or polymer material and may e.g. contain inorganic filler materials configured to reduce the thermal resistance of the encapsulation. Various techniques may be employed to encapsulate the semiconductor die(s) with the encapsulation material, for example compression molding, injection molding, transfer molding, or lamination.

An efficient power semiconductor module, an efficient power electronic system and an efficient method for fabricating a power semiconductor module may for example reduce material consumption, ohmic losses, chemical waste, etc. and may thus enable energy and/or resource savings. Improved power semiconductor modules, improved power electronic systems and improved methods for fabricating a power semiconductor module, as specified in this description, may thus at least indirectly contribute to green technology solutions, i.e. climate-friendly solutions providing a mitigation of energy and/or resource use.

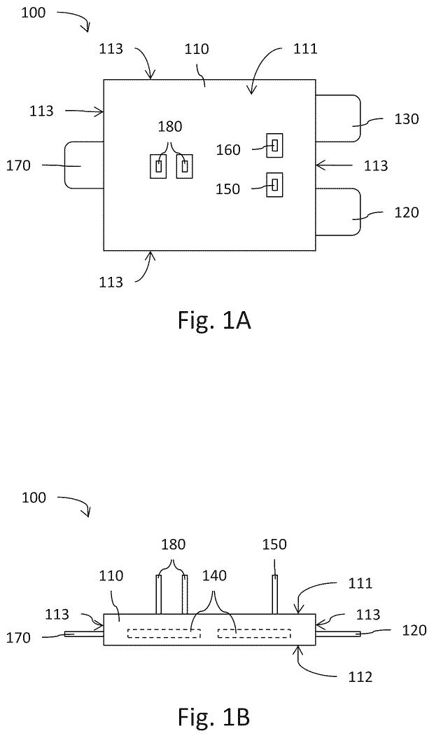

FIGS. 1A and 1B show a power semiconductor module 100 comprising an encapsulation body 110, a first power lead 120, a second power lead 130, a plurality of power semiconductor dies 140, a first pin 150 and a second pin 160. FIG. 1A shows a top down view and FIG. 1B shows a side view of the power semiconductor module 100. The power semiconductor dies 140 are omitted from FIG. 1A and are shown with dashed lines in FIG. 1B since the encapsulation body 110 obstructs the view onto the power semiconductor dies 140.

The power semiconductor module 100 may comprise any suitable electrical circuit, for example a converter circuit, an inverter circuit, a half bridge circuit, a full bridge circuit, etc. The power semiconductor module 100 may be configured to operate with a high electrical voltage and or a strong electrical current, for example a voltage of 100V or more, or 500V or more, or 1 kV or more and/or a current of 1 A or more, or 10 A or more. The power semiconductor module 100 may for example be configured for use in automotive applications.

The encapsulation body 110 comprises a first side 111, an opposite second side 112 and lateral sides 113 connecting the first and second sides 111, 112. The lateral sides 113 may for example have a smaller surface area than the first and second sides 111, 112. The first and second sides 111, 112 may for example have about the same surface area or exactly the same surface area.

The power semiconductor module 100 may have any suitable shape and any suitable dimensions. For example, the power semiconductor module 100 may have an essentially rectangular or quadratic shape as viewed from above the first side 111. The first side 111 may for example have an edge length of 1 cm or more, or 5 cm or more, or 10 cm or more, or 15 cm or more.

According to an example, the encapsulation body 110 comprises or consists of a molded body. Such a molded body may for example be fabricated using a technique like compression molding, injection molding or transfer molding. According to another example, the encapsulation body 110 comprises a plastic frame defining an interior volume, wherein the power semiconductor dies 140 are arranged within the interior volume. A potting material may be deposited on the power semiconductor dies 140 and may at least partially fill the interior volume.

The power semiconductor module 100 may for example be configured for single side cooling, meaning that a single side of the encapsulation body 110 is configured to be coupled to a heatsink. For example, the second side 112 of the encapsulation body 110 may be configured to be coupled to a heatsink. The first side 111 may for example be configured to face a driver board. According to another example, the power semiconductor module 100 may be configured for double sided cooling, wherein both the first and second sides 111, 112 are configured to be coupled to heatsinks. In this case, a driver board may e.g. be arranged above such a heatsink.

The first power lead 120 and the second power lead 130 are exposed from a first one of the lateral sides 113 of the encapsulation body 110. The first and second power leads 120, 130 may be arranged side-by-side. The first and second power leads 120, 130 may be arranged coplanar. However, it is also possible that the first and second power leads 120, 130 are arranged in different planes relative to each other.

The first and second power leads 120, 130 may comprise or consist of any suitable metal or metal alloy. The first and second power leads 120, 130 may for example comprise or consist of Al or Cu. According to an example, the first and second power leads 120, 130 are coated with a suitable plating, e.g. a Ni plating. According to an example, the first and second power leads 120, 130 are leadframe parts.

The first power lead 120 is configured to provide a first DC+ connection (i.e. a direct current connection with a positive voltage) for the power semiconductor module 100 (in particular, for the power semiconductor dies 140) and the second power lead 130 is configured to provide a first DC− connection (i.e. a direct current connection with a negative voltage) for the power semiconductor module 100.

According to an example, the power semiconductor module 100 may comprise a further power lead 170 which may for example be configured to provide a phase connection for the power semiconductor module 100. The further power lead 170 may comprise or consist of the same material as the first and second power leads 120, 130 and may also be a leadframe part. The further power lead 170 may for example be exposed from a second one of the lateral sides 113 of the encapsulation body 110. The second lateral side 113 may for example be opposite to the first lateral side 113 comprising the first and second power leads 120, 130.

According to an example, the power semiconductor module 100 may comprise even further power leads. For example, the power semiconductor module 100 may comprise one or more further power leads which are configured to be part of the first DC+ connection and/or one or more further power leads which are configured to be part of the first DC− connection and/or one or more further power leads which are configured to be part of the phase connection.

The power semiconductor dies 140 are encapsulated by the encapsulation body 110 and are electrically connected to the first and second power leads 120, 130. Although the power semiconductor module 100 so far has been described as having at least two power semiconductor dies 140, it is of course also possible that the power semiconductor module 100 comprises e.g. two power transistor circuits provided in monolithic integration.

The power semiconductor dies 140 may be arranged over one or more carriers (not shown). For example, the power semiconductor dies 140 may be soldered or sintered or glued with conductive glue to the carrier(s). The power leads 120, 130, 170 and possibly the first and second pins 150, 160 and possibly the further pins 180 (see below) may also be arranged over the carrier(s). The power semiconductor dies 140 and the power leads 120, 130, 170 may for example be electrically connected via the carrier(s).

The carrier(s) may for example be power electronic substrates, e.g. substrates of the type direct copper bonded (DCB), direct aluminum bonded (DAB), active metal brazed (AMB), insulated metal substrate (IMS), etc. The carrier(s) may for example be exposed from the second side 112 of the encapsulation 110. In the case that the power semiconductor module 100 is configured for double sided cooling, a further carrier may be exposed from the first side 111.

According to an example, the power semiconductor module 100 is configured for particular fast switching of a load current. To this end, the power semiconductor module 100 may e.g. comprise power semiconductor dies 140 comprising or consisting of SiC or GaN. Due to this fast switching, it may be beneficial to address parasitic inductances in the power semiconductor module 100 as outlined further below.

The first and second pins 150, 160 are exposed from the encapsulation body 110. In the example shown in FIG. 1, the first and second pins 150, 160 are exposed from the first side 111 of the encapsulation body 110. It is, however, also possible that the first and second pins 150, 160 are e.g. exposed from one or more of the lateral sides 113.

The first and second pins 150, 160 are arranged perpendicular to the first and second power leads 120, 130. This may mean that the whole of the first and second pins 150, 160 or at least an upper end of the first and second pins 150, 160 points in a direction that is perpendicular to the first and second power leads 120, 130. The first and second pins 150, 160 may be configured to be connected to an external appliance (e.g. a driver board), wherein the external appliance may e.g. be arranged above the first side 111 of the encapsulation body 110 (this may be the reason why the first and second pins 150, 160 are arranged perpendicular to the first and second power leads 120, 130).

According to an example, the first and second pins 150, 160 are press-fit pins, configured to provide a press-fit connection with an external appliance. The first and second pins 150, 160 may comprise or consist of any suitable metal or metal alloy, e.g. Al or Cu. The first and second pins 150, 160 may comprise a suitable plating, e.g. a Ni plating.

The first pin 150 is configured to provide a second DC+ connection and the second pin 160 is configured to provide a second DC− connection of the power semiconductor module 100. This may in particular mean that the first pin 150 is electrically connected to the first power lead 120 and is at the same electrical potential as the first power lead 120 and the second pin 160 is electrically connected to the second power lead 130 and is at the same electrical potential as the second power lead 130.

According to an example, an external appliance like a driver board may be arranged over the first side 111 of the encapsulation body 110, wherein the external appliance comprises a first capacitor (e.g. a fast ceramic capacitor) which is connected to the first and second pins 150, 160 to provide a first commutation loop. Providing such a commutation loop, wherein the DC+ potential and DC− potential of the power leads 120, 130 are connected to the first capacitor, may e.g. help with reducing current overshoots. Due to a lower inductance of this commutation loop compared to the connection between the power leads 120, 130 and an external DC link capacitor, the current can commutate more quickly and overshoots between Drain-Source-voltages in the power semiconductor module 100 may be reduced.

Since the first and second pins 150, 160 may solely be configured to provide this commutation loop, the first and second pins 150, 160 need not necessarily be configured to carry a load current. Compared to the first and second power leads 120, 130, the first and second pins 150, 160 may therefore e.g. have a smaller cross section. For example, the cross section of the first and second pins 150, 160 may be less than half or less than one quarter of the cross section of the first and second power leads 120, 130.

According to an example, the power semiconductor module 100 may comprise one or more further pins 180 exposed from the encapsulation body 110. The one or more further pins 180 may for example be configured to transmit control signals for driving the power semiconductor dies 140. Additionally or alternatively, the one or more further pins 180 may be configured to transmit sensing signals, e.g. drain voltage sensing or source voltage sensing signals.

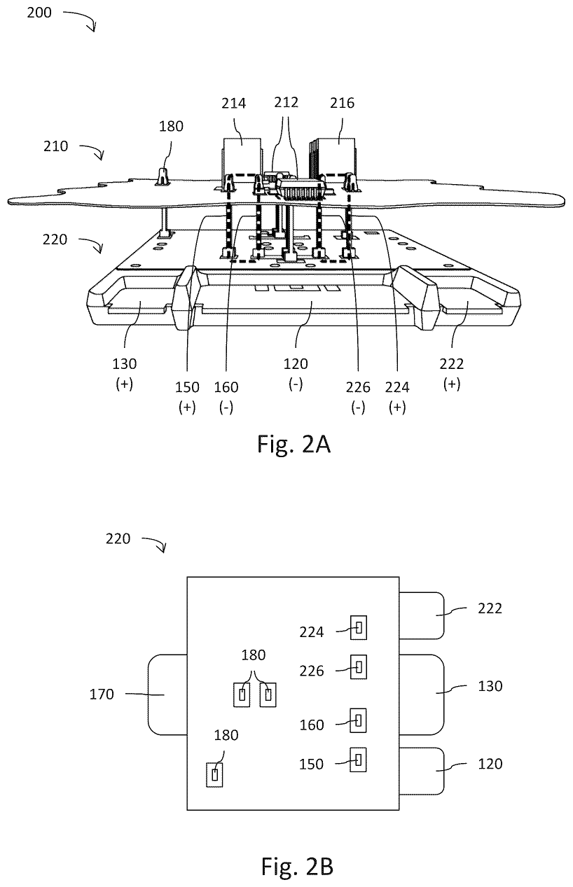

FIG. 2A shows a perspective view of a power electronic system 200 comprising a driver board 210 and a power semiconductor module 220. FIG. 2B shows a top down view of the power semiconductor module 220. The power semiconductor module 220 may be similar or identical to the power semiconductor module 100, except for the differences described in the following.

The power semiconductor module 220 comprises the first and second power leads 120, 130 and the power semiconductor module 220 additionally comprises a third power lead 222. The third power lead 222 may for example be configured to be part of the first DC+ connection, parallel to the first power lead 120 (this example is shown in FIG. 2A). According to another example, it is the other way around, meaning that the first and third power leads 120, 222 provide the first DC− connection and the second power lead 130 provides the first DC+ connection of the power semiconductor module 220.

The power semiconductor module 220 further comprises the first and second pins 150, 160 and the power semiconductor module 220 additionally comprises a third pin 224 and a fourth pin 226. The first pin 150 may be connected in parallel with the first power lead 120, the second and fourth pins 160, 226 may be connected in parallel with the second power lead 130 and the third pin 224 may be connected in parallel with the third power lead 222. The first and third pins 150, 224 may be configured to provide the second DC+ connection and the second and fourth pins 160, 226 may be configured to provide the second DC− connection (this example is shown in FIG. 2A). According to another example, it is the other way around.

The driver board 210 may for example comprise a printed circuit board (PCB). The driver board 210 comprises driver circuitry 212 configured to drive the power semiconductor dies of the power semiconductor module 220. The driver circuitry 212 may in particular be connected to gate electrodes of the power semiconductor dies of the power semiconductor module 220. The driver circuitry 212 may be connected to the power semiconductor module 220 via one or more further pins 180.

The driver board 210 further comprises a first capacitor 214 connected to the first and second pins 150, 160 to provide a first commutation loop and a second capacitor 216 connected to the third and fourth pins 224, 226 to provide a second commutation loop. In FIG. 2A, the first and second commutation loops are indicated by dashed lines. The capacitors 214, 216 may for example be fast ceramic capacitors. The first, second and third power leads 120, 130, 222 may be configured to be connected to an external DC link capacitor, e.g. via welding, soldering or screwing. Such a DC link capacitor may for example be a foil winded capacitor and may be comparatively large. Furthermore, such a DC link capacitor may have a comparatively high capacitance. The first and second capacitors 214, 216 may have a smaller capacitance than the DC link capacitor and/or may be faster than the DC link capacitor.

According to an example, the first and second capacitors 214, 216 each have a capacitance in the range of about 100 nF to about 1 μF. The lower limit of this range may also be about 200 nF or about 400 nF and the upper limit may also be about 800 nF or about 600 nF. A DC link capacitor on the other hand may e.g. have a capacitance in the range of 100 μF to 1 mF. In other words, the capacitances of the first and second capacitors 214, 216 may be a factor of 100 or more or a factor of 1000 or more smaller than a capacitance of a dedicated DC link capacitor.

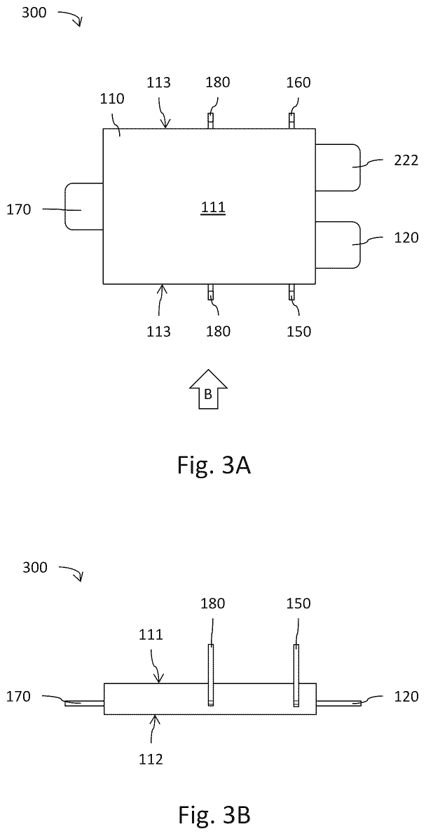

FIGS. 3A and 3B show a further power semiconductor module 300 which may be similar or identical to the power semiconductor modules 100 and 220, except for the differences described in the following. FIG. 3A shows a top down view of the power semiconductor module 300 and FIG. 3B shows a side view along the arrow B in FIG. 3A.

In the power semiconductor module 300, the first pin 150 and the second pin 160 are exposed from one or more of the lateral sides 113 of the encapsulation body 110. In particular, the first and second pins 150, 160 may be exposed from opposite ones of the lateral sides 113 (compare FIG. 3A). Furthermore, the first and second pins 150, 160 may each comprise a first portion arranged in a first plane and a second portion arranged in a different second plane, wherein the first and second planes are arranged at a non-zero angle relative to each other. The non-zero angle may for example be about 90°. The first and second power leads 120, 130 may for example be arranged in the first plane. In other words, the first and second pins 150, 160 may be bent upwards such that the second portion of the first and second pins is arranged perpendicular to the first and second power leads 120, 130.

The power semiconductor module 300 may also comprise the one or more further pins 180. The one or more further pins 180 may also be exposed from one or more of the lateral sides 113 of the encapsulation body 110 (for example, the one or more further pins 180 may be exposed from the same lateral sides 113 as the first and second pins 120, 130, compare FIG. 3A).

The power semiconductor module 300 may for example be configured for double sided cooling. This may in particular mean that a first carrier (e.g. a DCB) is exposed from the first side 111 of the encapsulation body 110 and a second carrier (e.g. a DCB) is exposed from the second side 112 of the encapsulation body 110. This may be the reason why the pins 150, 160, 180 are exposed from the lateral sides 113 of the encapsulation body 110.

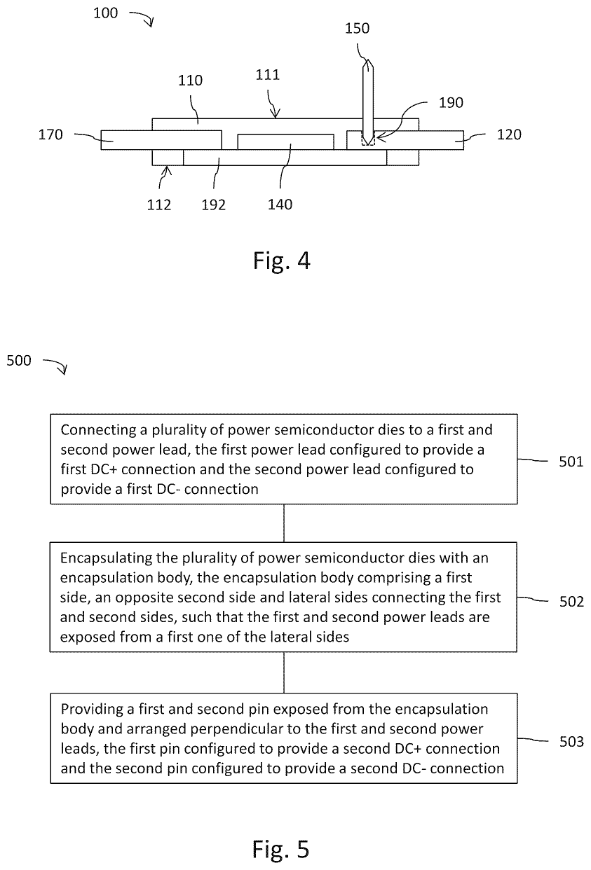

FIG. 4 shows a sectional view of the power semiconductor module 100 according to a specific example.

As shown in FIG. 4, the first pin 150 may be in direct contact with the first power lead 120. In a similar manner, the second pin 160 may be in direct contact with the second power lead 130. This may for example mean that lower ends of the first and second pins 150, 160 are inserted into respective recesses 190 in the first and second power leads 120, 130.

According to an example, the first and second power leads 120, 130 are metal clips. The recesses 190 may be fabricated in the metal clips using any suitable process, e.g. a punching process or a drilling process. The first and second pins 150, 160 and the recesses 190 may for example form press-fit connections.

As shown in FIG. 4, the lower ends of the first and second pins 150, 160 may be tapered in order to make inserting the pins 150, 160 into the recesses 190 easier. Upper ends of the pins 150, 160 may also be tapered in order to make inserting the pins 150, 160 into through holes of a driver board like the driver board 210 easier.

According to an example, the first and second power leads 120, 130 (and possibly also the further power lead 170) and the power semiconductor die(s) 140 are arranged on a carrier 192. The power leads 120, 130 (and 170) and the power semiconductor die(s) 140 may for example be soldered or sintered or glued with conductive glue onto the carrier 192. The carrier 192 may for example be a power electronic substrate, e.g. a power electronic substrate of one the types mentioned further above.

FIG. 5 is a flow chart of a method 500 for fabricating a power semiconductor module. The method 500 may for example be used to fabricate the power semiconductor modules 100, 220 or 300.

The method 500 comprises at 501 a process of connecting a plurality of power semiconductor dies to a first and second power lead, the first power lead configured to provide a first DC+ connection and the second power lead configured to provide a first DC− connection; at 502 a process of encapsulating the plurality of power semiconductor dies with an encapsulation body, the encapsulation body comprising a first side, an opposite second side and lateral sides connecting the first and second sides, such that the first and second power leads are exposed from a first one of the lateral sides; and at 503 a process of providing a first and second pin exposed from the encapsulation body and arranged perpendicular to the first and second power leads, the first pin configured to provide a second DC+ connection and the second pin configured to provide a second DC− connection.

According to an example of the method 500, the first and second pins 150, 160 are provided after the power semiconductor dies 140 have been encapsulated. This may entail fabricating (e.g. by molding) the encapsulation body 110 such that openings for the pins are provided. Alternatively, such openings may be fabricated after the encapsulation body 110 has been fabricated by removing part of the encapsulation 110 body by e.g. drilling, cutting, grinding, etc.

In the following, the power semiconductor module, the power electronic system and the method for fabricating a power electronic system are explained using specific examples.

Example 1 is a power electronic system, comprising: a power semiconductor module, comprising: an encapsulation body comprising a first side, an opposite second side and lateral sides connecting the first and second sides, a first and a second power lead exposed from a first one of the lateral sides, the first power lead configured to provide a first DC+ connection and the second power lead configured to provide a first DC− connection, a plurality of power semiconductor dies encapsulated by the encapsulation body and connected to the first and second power leads, a first and a second pin exposed from the encapsulation body and arranged perpendicular to the first and second power leads, the first pin configured to provide a second DC+ connection and the second pin configured to provide a second DC− connection; and a driver board arranged over the first side of the encapsulation body and comprising driver circuitry configured to drive the power semiconductor dies of the power semiconductor module, wherein the driver board further comprises a first capacitor connected to the first and second pins to provide a first commutation loop.

Example 2 is the power electronic system of example 1, wherein the first and second pins are press-fit pins.

Example 3 is the power electronic system of example 1 or 2, wherein the first and second power leads are connected to a direct current link capacitor via soldered joints, welded joints or joints comprising screws.

Example 4 is the power electronic system of one of the preceding examples, wherein the first capacitor has a capacitance in the range of 50 nF to 2000 nF.

Example 5 is the power electronic system of one of the preceding examples, wherein the first and second power leads are metal clips and wherein lower ends of the first and second pins are in direct contact with the metal clips.

Example 6 is the power electronic system of example 5, wherein the lower ends of the first and second pins are inserted into recesses in the metal clips.

Example 7 is the power electronic system of one of the preceding examples, wherein the first and second pins are exposed from the first side of the encapsulation body.

Example 8 is the power electronic system of one of examples 1 to 6, wherein the first and second pins are exposed from one or more of the lateral sides of the encapsulation body and wherein the first and second pins are bent upwards to be perpendicular to the first and second power leads.

Example 9 is the power electronic system of one of the preceding examples, wherein the encapsulation body is a molded body.

Example 10 is the power electronic system of one of examples 1 to 8, wherein the encapsulation body comprises a plastic frame, wherein the power semiconductor dies are arranged within an interior volume defined by the plastic frame.

Example 11 is the power electronic system of one of the preceding examples, wherein a load current flows through the first and second power leads but not through the first and second pins.

Example 12 is a power semiconductor module, comprising: an encapsulation body comprising a first side, an opposite second side and lateral sides connecting the first and second sides; a first and a second power lead exposed from a first one of the lateral sides, the first power lead configured to provide a first DC+ connection and the second power lead configured to provide a first DC− connection; a plurality of power semiconductor dies encapsulated by the encapsulation body and connected to the first and second power leads; and a first and a second pin exposed from the encapsulation body and arranged perpendicular to the first and second power leads, the first pin configured to provide a second DC+ connection and the second pin configured to provide a second DC− connection.

Example 13 is the power semiconductor module of example 12, wherein the first and second pins are press-fit pins.

Example 14 is the power semiconductor module of example 12 or 13, wherein the first and second power leads are configured to be connected to an external appliance via soldered joints, welded joints or joints comprising screws.

Example 15 is the power semiconductor module of one of examples 12 to 14, wherein the power semiconductor dies are connected to form a half bridge circuit.

Example 16 is a method for fabricating a power semiconductor module, the method comprising: connecting a plurality of power semiconductor dies to a first and second power lead, the first power lead configured to provide a first DC+ connection and the second power lead configured to provide a first DC− connection; encapsulating the plurality of power semiconductor dies with an encapsulation body, the encapsulation body comprising a first side, an opposite second side and lateral sides connecting the first and second sides, such that the first and second power leads are exposed from a first one of the lateral sides; and providing a first and second pin exposed from the encapsulation body and arranged perpendicular to the first and second power leads, the first pin configured to provide a second DC+ connection and the second pin configured to provide a second DC− connection.

Example 17 is the method of example 16, wherein the first and second pins are provided after the power semiconductor dies have been encapsulated.

Example 18 is the method of example 16 or 17, wherein providing the first and second pins comprises inserting lower ends of the first and second pins into recesses in the first and second power leads.

Example 19 is an apparatus comprising means for performing the method according to anyone of examples 16 to 18.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

What is claimed is:

1. A power electronic system, comprising:
a power semiconductor module, comprising:
an encapsulation body comprising a first side, an opposite second side, and lateral sides connecting the first and second sides;
a first and a second power lead exposed from a first one of the lateral sides, the first power lead configured to provide a first DC+ connection and the second power lead configured to provide a first DC− connection;
a plurality of power semiconductor dies encapsulated by the encapsulation body and connected to the first and second power leads;
a first and a second pin exposed from the encapsulation body and arranged perpendicular to the first and second power leads, the first pin configured to provide a second DC+ connection and the second pin configured to provide a second DC− connection; and
a driver board arranged over the first side of the encapsulation body and comprising driver circuitry configured to drive the power semiconductor dies of the power semiconductor module,
wherein the driver board further comprises a first capacitor connected to the first and second pins to provide a first commutation loop.

2. The power electronic system of claim 1, wherein the first and second pins are press-fit pins.

3. The power electronic system of claim 1, wherein the first and second power leads are connected to a direct current link capacitor via soldered joints, welded joints or joints comprising screws.

4. The power electronic system of claim 1, wherein the first capacitor has a capacitance in a range of 50 nF to 2000 nF.

5. The power electronic system of claim 1, wherein the first and second power leads are metal clips, and wherein lower ends of the first and second pins are in direct contact with the metal clips.

6. The power electronic system of claim 5, wherein the lower ends of the first and second pins are inserted into recesses in the metal clips.

7. The power electronic system of claim 1, wherein the first and second pins are exposed from the first side of the encapsulation body.

8. The power electronic system of claim 1, wherein the first and second pins are exposed from one or more of the lateral sides of the encapsulation body, and wherein the first and second pins are bent upwards to be perpendicular to the first and second power leads.

9. The power electronic system of claim 1, wherein the encapsulation body is a molded body.

10. The power electronic system of claim 1, wherein the encapsulation body comprises a plastic frame, and wherein the power semiconductor dies are arranged within an interior volume defined by the plastic frame.

11. The power electronic system of claim 1, wherein a load current flows through the first and second power leads but not through the first and second pins.

12. A power semiconductor module, comprising:
an encapsulation body comprising a first side, an opposite second side, and lateral sides connecting the first and second sides;
a first and a second power lead exposed from a first one of the lateral sides, the first power lead configured to provide a first DC+ connection and the second power lead configured to provide a first DC− connection;
a plurality of power semiconductor dies encapsulated by the encapsulation body and connected to the first and second power leads; and
a first and a second pin exposed from the encapsulation body and arranged perpendicular to the first and second power leads, the first pin configured to provide a second DC+ connection and the second pin configured to provide a second DC− connection.

13. The power semiconductor module of claim 12, wherein the first and second pins are press-fit pins.

14. The power semiconductor module of claim 12, wherein the first and second power leads are configured to be connected to an external appliance via soldered joints, welded joints or joints comprising screws.

15. The power semiconductor module of claim 12, wherein the power semiconductor dies are connected to form a half bridge circuit.

16. A method for fabricating a power semiconductor module, the method comprising:
connecting a plurality of power semiconductor dies to a first and second power lead, the first power lead configured to provide a first DC+ connection and the second power lead configured to provide a first DC− connection;
encapsulating the plurality of power semiconductor dies with an encapsulation body, the encapsulation body comprising a first side, an opposite second side, and lateral sides connecting the first and second sides, such that the first and second power leads are exposed from a first one of the lateral sides; and
providing a first and a second pin exposed from the encapsulation body and arranged perpendicular to the first and second power leads, the first pin configured to provide a second DC+ connection and the second pin configured to provide a second DC− connection.

17. The method of claim 16, wherein the first and second pins are provided after the power semiconductor dies have been encapsulated.

18. The method of claim 16, wherein providing the first and second pins comprises inserting lower ends of the first and second pins into recesses in the first and second power leads
